(19) United States
(12) Patent Application Publication
(10) Pub. No.: US 2013/0014810 A1
(43) Pub. Date: Jan. 17, 2013

(54) PHOTOELECTRIC CONVERSION DEVICE

(71) Applicants: Yoshikazu YAMAOKA, Ogaki-shi (JP); Shigeo YATA, Ogaki-shi (JP)

(72) Inventors: Yoshikazu YAMAOKA, Ogaki-shi (JP); Shigeo YATA, Ogaki-shi (JP)

(73) Assignee: Sanyo Electric Co., Ltd., Moriguchi-shi (JP)

(21) Appl. No.: 13/614,788

(22) Filed: Sep. 13, 2012

Related U.S. Application Data
(63) Continuation of application No. PCT/JP2011/060043, filed on Apr. 25, 2011.

(30) Foreign Application Priority Data
Apr. 28, 2010 (JP) 2010-14455

(51) Int. Cl. H01L 31/06

(52) U.S. Cl. 136/252

(57) ABSTRACT

In order to increase the photoelectric conversion efficiency of a photoelectric conversion device, a photoelectric conversion device (400), obtained by layering semiconductor layers consisting of a p-type layer (42), an i-type layer (46) and an n-type layer (50), is provided with a first intermediate layer (44) and a second intermediate layer (48), which abut the i-type layer (46) and have refractive indices that increase from the side that abuts the i-type layer (46) to the side that does not abut the i-type layer (46) within a range of refractive indices lower than that of the i-type layer.

### CROSS-REFERENCE TO RELATED APPLICATIONS

The present application is a continuation application of International Application No. PCT/JP2011/060043, filed Apr. 25, 2011, the entire contents of which are incorporated herein by reference and priority to which is hereby claimed. The PCT/JP2011/060043 application claimed the benefit of the date of the earlier filed Japanese Patent Application No. 2010-104455 filed Apr. 28, 2010, the entire contents of which are incorporated herein by reference, and priority to which is hereby claimed.

### TECHNICAL FIELD

The present invention relates to a photoelectric conversion device, and more particularly to a photoelectric conversion device comprising an intermediate layer.

### BACKGROUND ART

Solar cells using polycrystalline, microcrystalline or amorphous silicon are known. In particular, photoelectric conversion devices having a structure laminating thin films of microcrystalline silicon or amorphous silicon are attracting attention from the viewpoints of resource consumption, cost reduction, and efficiency.

In general, a photoelectric conversion device is formed by laminating in sequence on a substrate having an insulating surface, a first electrode layer, one or more semiconductor thin-film photoelectric conversion units, and a second electrode layer. Each photoelectric conversion unit is formed by laminating from the light incident side a p-type layer, an i-type layer, and an n-type layer. Laminating two or more photoelectric conversion units in the light incident direction is known as a method for improving the conversion efficiency of the photoelectric conversion device. A first photoelectric conversion unit including a photoelectric conversion layer having a wide bandgap is arranged on the light incident side of the photoelectric conversion device and behind thereof a second photoelectric conversion unit including a photoelectric conversion layer having a narrower bandgap than the first photoelectric conversion unit is arranged. As a result, photoelectric conversion becomes possible across a wide wavelength range of incident light and an improvement in conversion efficiency for the overall device can be designed.

For example, as shown in FIG. 12, a photoelectric conversion device 100 is known where, after a transparent electrode layer 12 is formed on a substrate 10, a tandem structure is formed having an amorphous silicon photoelectric conversion unit (a-Si unit) 14 as a top cell and a microcrystalline photoelectric conversion unit (μc-Si unit) 16 as a bottom cell, and thereon a rear electrode layer 18 is formed.

In the tandem type photoelectric conversion device 100, a known structure (refer to patent document 1) provides an intermediate layer 20 between the a-Si unit 14 and the μc-Si unit 16. In the intermediate layer 20, zinc oxide (ZnO) or silicon oxide (SiOx), for example, is used. Furthermore, in the intermediate layer 20, silicon oxide material, silicon carbide material, silicon nitride material, or carbon material, such as diamond-like carbon, can also be used. The intermediate layer 20 has a light refractive index lower than the a-Si unit 14 so that reflection of light to the a-Si unit 14 occurs between the a-Si unit 14, which is on the light incident side, and the intermediate layer 20.

### PRIOR ART DOCUMENT

### Patent Document

Patent Document 1: Japanese Patent Laid-Open Publication No. 2004-260014

### SUMMARY OF THE INVENTION

### Objects to be Achieved by the Invention

However, when light is reflected to the a-Si unit 14 on the light incident side at the intermediate layer 20, the refractive index becomes lower with the a-Si unit 14, the transparent electrode layer 12, the substrate 10, and air so that the light reflected to the a-Si unit 14 side passes through the substrate 10 causing a problem where the light cannot be fully utilized.

### Means for Achieving the Objects

One mode of the present invention is a photoelectric conversion device, in which are laminated semiconductor layers of a p-type layer, an i-type layer, and an n-type layer, comprising an intermediate layer abutting the i-type layer and having a refractive index increasing from a side that abuts the i-type layer toward a side that does not abut the i-type layer within a range of refractive indices lower than that of the i-type layer.

### Effects of the Invention

According to the present invention, light utilization efficiency in the photoelectric conversion device is increased and the photoelectric conversion efficiency can be improved.

### BRIEF DESCRIPTION OF THE DRAWINGS

FIG. 1 is a schematic cross sectional view showing a structure of a photoelectric conversion device of a first embodiment.

FIG. 2 shows the refractive index of the photoelectric conversion device of the first embodiment.

FIG. 3 shows another example of the refractive index of the photoelectric conversion device of the first embodiment.

FIG. 4 is a schematic cross sectional view showing a structure of a photoelectric conversion device of a second embodiment.

FIG. 5 is a schematic cross sectional view showing a structure of a photoelectric conversion device of a third embodiment.

FIG. 6 shows the refractive index of the photoelectric conversion device of the third embodiment.

FIG. 7 shows another example of the refractive index of the photoelectric conversion device of the third embodiment.

FIG. 8 is a schematic cross sectional view showing a structure of a photoelectric conversion device of a fourth embodiment.

FIG. 9 is a schematic cross sectional view showing a structure of a photoelectric conversion device of a fifth embodiment.

FIG. 10 shows the refractive index of the photoelectric conversion device of the fifth embodiment.

FIG. 11 shows another example of the refractive index of the photoelectric conversion device of the fifth embodiment.

FIG. 12 is a schematic cross sectional view showing a structure of a conventional photoelectric conversion device.

### BEST MODE FOR CARRYING OUT THE INVENTION

### First Embodiment

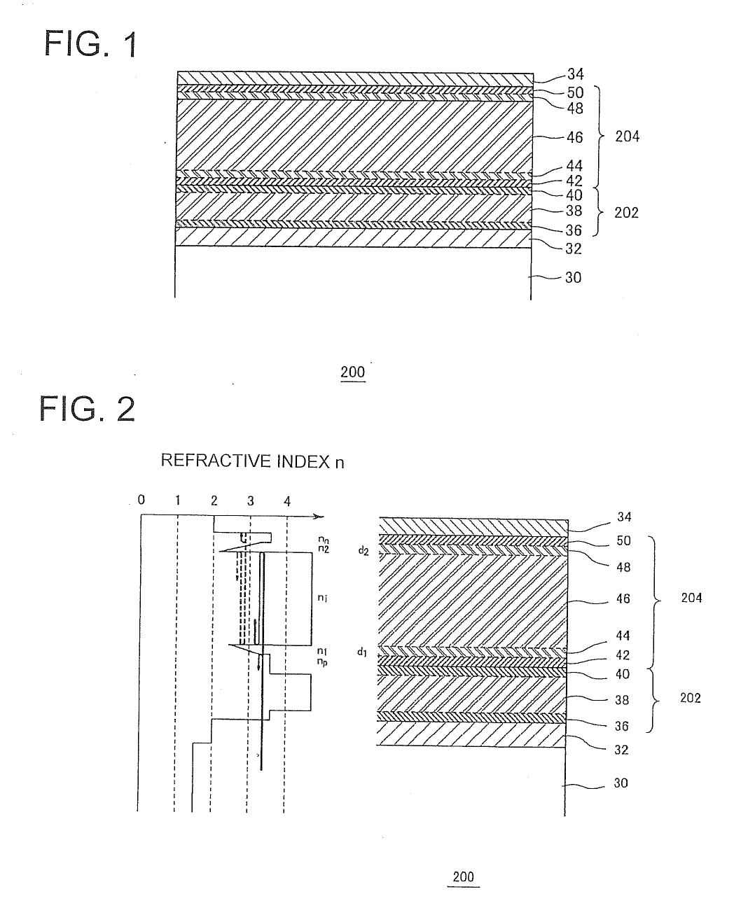

FIG. 1 is a cross sectional view showing a structure of a photoelectric conversion device 200 of the first embodiment. The photoelectric conversion device 200 of the embodiment has a structure, with a transparent insulation substrate 30 as the light incident side, laminating from the light incident side, a transparent conductive layer 32, an amorphous silicon photoelectric conversion unit (a-Si unit) 202 as a top cell having a wide bandgap, a microcrystalline silicon photoelectric conversion unit (μc-Si unit) 204 as a bottom cell having a narrower bandgap than the a-Si unit 202, and a rear electrode layer 34.

The transparent insulation substrate 30 can comprise a material having at least transparency in the visible light wavelength region, such as a glass substrate or a plastic substrate, for example. The transparent conductive layer 32 is formed on the transparent insulation substrate 30. The transparent conductive later 32 preferably uses at least one or a combination of several from among transparent conductive oxides (TCO), such as tin dioxide (SnO₂), zinc oxide (ZnO), or indium tin oxide (ITO) doped with tin (Sn), antimony (Sb), fluorine (F), or aluminum (Al). In particular, zinc oxide (ZnO) is preferable due to its high translucency, low resistivity, and superior plasma resistance. The transparent conductive layer 32 can be formed, for example, from sputtering or CVD. The film thickness of the transparent conductive layer 32 is preferably in a range from 0.5 μm to 5 μm. Furthermore, it is preferable to provide the transparent conductive layer 32 with a textured surface having a light trapping effect.

The a-Si unit 202 is formed by laminating, in sequence on the transparent conductive layer 32, silicon based thin films of a p-type layer 36, an i-type layer 38, and an n-type layer 40. The a-Si unit 202 can be formed by plasma CVD by selecting and mixing gases from silicon containing gas, such as silane (SiH₄), disilane (Si₂H₆), and dichlorosilane (SiH₂Cl₂), hydrocarbon gas, such as methane (CH₄), p-type dopant containing gas, such as diborane (B₂H₆), n-type dopant containing gas, such as phosphine (PH₃), and dilution gas, such as hydrogen (H₂), bringing the gaseous mixture into a plasma state, and performing film forming. Specific film forming conditions are shown in Table 1.

TABLE 1

| | | Substrate | | Reaction | |
|---|---|---|---|---|---|
| | | Temperature | Gas Flow | Pressure | RF Power |
| | Layer | (° C.) | (sccm) | (Pa) | (kW) |
| a-Si | p-type | 180 | SiH₄: 75 | 80 | 56 |
| unit | layer 36 | | CH₄: 150 | | (0.01 W/cm²) |
| 202 | | | H₂: 750 | | |
| | | | B₂H₆: 2-23 | | |
| | i-type | 180 | SiH₄: 600 | 100 | 60 |
| | layer 38 | | H₂: 2000 | | (0.012 W/cm²) |
| | n-type | 180 | SiH₄: 20 | 200 | 600 |
| | layer 40 | | H₂: 4000 | | (0.012 W/cm²) |
| | | | PH₃: 10 | | |

The plasma CVD method preferably employs, for example, RF plasma CVD at 13.56 MHz. RF plasma CVD can be of the parallel plate type. Generally, the films for the p-type layer 36, the i-type layer 38, and the n-type layer 40 are formed in separate film formation chambers. The film formation chambers can be vacuum pumped by a vacuum pump and electrodes for RF plasma CVD are internal. Furthermore, a transport unit for the transparent insulation substrate 30, a power supply and a matching unit for RF plasma CVD, and tubing for gas supply are provided.

The p-type layer 36 is formed on the transparent conductive layer 32. The p-type layer 36 is preferably a p-type amorphous silicon layer (p-type a-Si:H) or a p-type amorphous silicon carbide layer (p-type a-SiC:H) doped with a p-type dopant (such as boron) having a film thickness from 10 nm to 100 nm. The film property of the p-type layer 36 can be changed by adjusting the mixture ratio of silicon containing gas, hydrocarbon gas, p-type dopant containing gas, and dilution gas, the pressure, and the high frequency power for plasma generation. The i-type layer 38 is an amorphous layer without doping having a film thickness from 50 nm to 500 nm and formed on the p-type layer 36. The film property of the i-type layer 38 can be changed by adjusting the mixture ratio of silicon containing gas and dilution gas, the pressure, and the high frequency power for plasma generation. The i-type layer 38 is the power generating layer of the a-Si unit 202. The n-type layer 40 is an n-type amorphous silicon layer (n-type a-Si:H) or an n-type microcrystalline silicon layer (n-type μc-Si:H) doped with an n-type dopant (such as phosphorous) having a film thickness from 10 nm to 100 nm and formed on the i-type layer 38. The film property of the n-type layer 40 can be changed by adjusting the mixture ratio of silicon containing gas, hydrocarbon gas, n-type dopant containing gas, and dilution gas, the pressure, and the high frequency power for plasma generation.

Next, the μc-Si unit 204 is formed by laminating in sequence a p-type layer 42, a first intermediate layer 44, an i-type layer 46, a second intermediate layer 48, and an n-type layer 50. The μc-Si unit 204 can be formed by plasma CVD by selecting and mixing gases from silicon containing gas, such as silane (SiH₄), disilane (Si₂H₆), and dichlorosilane (SiHCl₂), hydrocarbon gas, such as methane (CH₄), p-type dopant containing gas, such as diborane (B₂H₆), n-type dopant containing gas, such as phosphine (PH₃), oxygen containing gas, such as carbon dioxide (CO₂), and dilution gas, such as hydrogen (H₂), bringing the gaseous mixture into a plasma state, and performing film forming. Specific film forming conditions are shown in Table 2.

TABLE 2

| | | Substrate | | Reaction | | |
|---|---|---|---|---|---|---|
| | | Temperature | Gas Flow | Pressure | | |
| | Layer | (° C.) | (sccm) | (Pa) | Frequency | RF Power (kW) |
| μc- | p-type layer | 200 | SiH₄: 25 | 106 | RF | 250 |
| Si | 42 | | H₂: 5000 | | | (0.05 W/cm²) |
| unit | | | B₂H₆: 5 | | | |
| 204 | First | 180 | SiH₄: 20 | 200 | RF | 56 |
| | intermediate | | CO₂: 40→ | | | (0.15 W/cm²) |
| | layer 44 | | 20 | | | |
| | | | H₂: 6000 | | | |
| | | | B₂H₆: 90 | | | |
| | | | →40 | | | |
| | i-type layer | 180 | SiH₄: 300 | 9600-10000 | VHF | 2500 |
| | 46 | | H₂: 14000 | | (27 MHz) | (0.5 W/cm²) |
| | Second | 180 | SiH₄: 20 | 200 | RF | 56 |
| | intermediate | | CO₂: 20→ | | | (0.15 W/cm²) |
| | layer 48 | | 40 | | | |
| | | | H₂: 6000 | | | |
| | | | PH₃: 40→ | | | |
| | | | 90 | | | |
| | n-type layer | 200 | SiH₄: 25 | 133 | RF | 1500 |
| | 50 | | H₂: 5000 | | | (0.3 W/cm²) |
| | | | PH₃: 25 | | | |

Similar to the a-Si unit 202, the plasma CVD preferably employs, for example, RF plasma CVD at 13.56 MHz. Generally, the films for the p-type layer 42, the i-type layer 46, and the n-type layer 50 are formed in separate film formation chambers. Furthermore, the films for the first intermediate layer 44 and the second intermediate layer 48 may be formed using the film formation chamber for one of the p-type layer 36, the n-type layer 40, the p-type layer 42, or the n-type layer 50.

The p-type layer 42 is formed on the n-type layer 40 of the a-Si unit 202. The p-type layer 42 is preferably a microcrystalline silicon layer, an amorphous silicon layer, or a combination thereof. The film property of the p-type layer 42 can be changed by adjusting the mixture ratio of silicon containing gas, hydrocarbon gas, p-type dopant containing gas, and dilution gas, the pressure, and the high frequency power for plasma generation.

The first intermediate layer 44 is formed on the p-type layer 40. The first intermediate layer 44, along with the second intermediate layer 48 to be described hereinafter, serves to trap light in the i-type layer 46, which is the power generating layer of the μc-Si unit 204. The first intermediate layer 44 is preferably a layer including silicon oxide doped with a p-type dopant (such as boron). For example, the first intermediate layer 44 is preferably formed by plasma CVD using a gaseous mixture mixing silicon containing gas, p-type dopant containing gas, and oxygen containing gas, such as carbon dioxide (CO₂) in dilution gas. The film property of the first intermediate layer 44 can be changed by adjusting the added gas type, the gas mixture ratio, the pressure, and the high frequency power for plasma generation.

FIG. 2 shows the refractive index of each layer of the photoelectric conversion device 200 of the embodiment. As shown in FIG. 2, a refractive index n₁ of the first intermediate layer 44 is lower than a refractive index nᵢ of the i-type layer 46 of the μc-Si unit 204 for which light is to be trapped. Furthermore, the refractive index n₁ of the first intermediate layer 44 is less than or equal to a refractive index nₚ of the abutting p-type layer 42. Moreover, in the embodiment, the refractive index of the first intermediate layer 44 has been set to change in the film thickness direction. The first intermediate layer 44 is formed so that the refractive index n₁ gradually increases from the i-type layer 46 side toward the p-type layer 42 side as shown in FIG. 2.

The refractive index n₁ of the first intermediate layer 44 is preferably set so as to be approximately equal to the refractive index nₚ of the p-type layer 42 in the interface with the p-type layer 42. More specifically, since the refractive index nₚ of the p-type layer 42 is approximately 3.6, the refractive index n₁ of the first intermediate layer 44 at the interface with the p-type layer 42 is preferably set so as to be approximately 3.6. Furthermore, the refractive index n₁ of the first intermediate layer 44 is preferably set as low as possible to an extent where the film property does not deteriorate at the interface with the i-type layer 46. More specifically, at the interface with the i-type layer 46, the refractive index n₁ of the first intermediate layer 44 is preferably set to approximately 2.1.

To change the refractive index n₁ of the first intermediate layer 44 in the film thickness direction, the mixture ratio of oxygen containing gas, such as carbon dioxide (CO₂), with respect to the gaseous mixture of silicon containing gas, dopant containing gas, and dilution gas, should be changed continuously during film formation. Namely, to lower the refractive index n₁ the mixture ratio of the oxygen containing gas, such as carbon dioxide (CO₂), should be adjusted so as to be higher. Furthermore, the refractive index n₁ of the first intermediate layer 44 can be changed also by adjusting the film formation conditions, such as the pressure during film formation and the high frequency power for plasma generation based on plasma CVD for the first intermediate layer 44.

The i-type layer 46 is formed on the first intermediate layer 44. The i-type layer 46 is a non-doped microcrystalline silicon film having a film thickness from 0.5 μm to 5 μm. The i-type layer 46 is a layer constituting a power generating layer of the μc-Si unit 204. The i-type layer 46 preferably has a laminated structure where a buffer layer is first formed and a main power generating layer is formed on the buffer layer. The buffer layer film is formed under film formation conditions having a higher crystalline fraction than the film formation conditions for the main power generating layer. Namely, when film formation is performed as a single film, such as on the glass substrate, the buffer layer is formed under film formation conditions having a higher crystalline fraction than the main power generating layer. The film property of the i-type layer 46 can be changed by adjusting the mixture ratio of silicon containing gas and dilution gas, the pressure, and the high frequency power for plasma generation.

The second intermediate layer 48 is formed on the i-type layer 46. The second intermediate layer 48 is preferably a layer containing silicon oxide doped with an n-type dopant (such as phosphorous). For example, the second intermediate layer 48 is preferably formed by plasma CVD using a gaseous mixture mixing oxygen containing gas, such as carbon dioxide (CO₂), with silicon containing gas, n-type dopant containing gas, and dilution gas. The film property of the second intermediate layer 48 can be changed by adjusting the added gas type, the gas mixture ratio, the pressure, and the high frequency power for plasma generation.

As shown in FIG. 2, a refractive index n₂ of the second intermediate layer 48 is lower than the refractive index nᵢ of the i-type layer 46 of the μc-Si unit 204 for which light is to be trapped. Furthermore, the refractive index n₂ of the second intermediate layer 48 is less than or equal to a refractive index nₙ of the abutting n-type layer 50. Moreover, in the embodiment, the second intermediate layer 48 is formed so that the refractive index n₂ thereof changes along the film formation direction. The second intermediate layer 48, as shown in FIG. 2, is formed so that the refractive index n₂ increases gradually from the i-type layer 46 side toward the n-type layer 50 side.

The refractive index n₂ of the second intermediate layer 48 is preferably approximately equal to the refractive index nₙ of the n-type layer 50 in the interface with the n-type layer 50. More specifically, since the refractive index nₙ of the n-type layer 50 is approximately 3.6, the refractive index n₂ of the second intermediate layer 48 is preferably set to approximately 3.6 at the interface with the n-type layer 50. Furthermore, the refractive index n₂ of the second intermediate layer 48 is preferably set as low as possible to an extent where the film property does not deteriorate at the interface with the i-type layer 46. More specifically, at the interface with the i-type layer 46, the refractive index n₂ of the second intermediate layer 48 is preferably set to approximately 2.1.

To change the refractive index n₂ of the second intermediate layer 48 in the film thickness direction, the mixture ratio of oxygen containing gas, such as carbon dioxide (CO₂), with respect to the gaseous mixture of silicon containing gas, dopant containing gas, and dilution gas, should be changed continuously during film formation. Namely, to lower the refractive index n₂ the mixture ratio of the oxygen containing gas, such as carbon dioxide (CO₂), should be adjusted so as to be higher. Furthermore, the refractive index n₂ of the second intermediate layer 48 can be changed also by adjusting the film formation conditions, such as the pressure during film formation and the high frequency power for plasma generation based on plasma CVD for the first intermediate layer 48.

The n-type layer 50 is formed on the second intermediate layer 48. The n-type layer 50 is an n-type microcrystalline silicon layer (n-type μc-Si:H) doped with an n-type dopant (such as phosphorous) having a film thickness from 5 nm to 50 nm. The film property of the n-type layer 50 can be changed by adjusting the mixture ratio of silicon containing gas, hydrocarbon gas, n-type dopant containing gas, and dilution gas, the pressure, and the high frequency power for plasma generation.

However, the μc-Si unit 204 of the embodiment is not limited to this provided an i-type microcrystalline layer (i-type μc-Si:H) is used in the i-type layer 46 constituting the power generating layer, and the first intermediate layer 44 and the second intermediate layer 48 sandwich the i-type layer 46.

The rear electrode layer 34 is formed on the μc-Si unit 204. The rear electrode layer 34 preferably has a laminated structure of a reflective metal and a transparent conductive oxide (TCO). For the transparent conductive oxide (TCO), tin dioxide (SnO₂), zinc oxide (ZnO), indium tin oxide (ITO), and so forth, or doped with an impurity is used. For example, zinc oxide (ZnO) doped with aluminum (Al) as an impurity may be used. Furthermore, for the reflective metal, a metal, such as silver (Ag) or aluminum (Al), is used. The transparent conductive oxide (TCO) and the reflective metal can be formed, for example, by sputtering or CVD. At least one of either the transparent conductive oxide (TCO) or the reflective metal is preferably provided with texture to increase the light trapping effect.

Furthermore, the rear electrode layer 34 may be covered with a protective film (not shown). The protective film should be a resin material, such as EVA or a polyimide, adhered so as to cover the rear electrode layer 34 by a sealant, which is a similar resin material. As a result, moisture penetration, for example, into the power generating layer of the photoelectric conversion device 200 can be prevented.

Using a YAG laser (fundamental wave 1064 nm, second harmonic 532 nm), a structure connecting multiple cells in series may be adopted by performing separation of the transparent conductive layer 32, the a-Si unit 202, the μc-Si unit 204, and the rear electrode layer 34.

Operations of the first intermediate layer 44 and the second intermediate layer 48 will be described hereinafter. As shown by the arrow (solid line) in FIG. 2, light penetrating the interface of the p-type layer 42 and the first intermediate layer 44 and entering the i-type layer 46 is reflected due to the mutual refractive index difference at the interface of the i-type layer 46 and the second intermediate layer 48 and returned to the i-type layer 46. Furthermore, when the light reflected at the interface of the i-type layer 46 and the second intermediate layer 48 reaches the interface of the i-type layer 46 and the first intermediate layer 44, the light is again reflected due to the mutual refractive index difference and returned to the i-type layer 46. In this manner, a light trapping effect at the i-type layer 46 of the μc-Si unit 204 constituting the bottom cell is obtained due to the first intermediate layer 44 and the second intermediate layer 48.

Furthermore, as shown by the arrow (dashed line) in FIG. 2, part of the light penetrates the interface of the i-type layer 46 and the second intermediate layer 48. However, the light passes the n-type layer 50, reaches the n-type layer 50 and the rear electrode layer 34, is reflected due to the refractive index difference of the n-type layer 50 and the rear electrode layer 34, passes the n-type layer 50 and the second intermediate layer 48, and is again returned to the i-type layer 46. Then, as described above, the light reflected by the rear electrode layer 34 is also trapped at the i-type layer 46 due to the first intermediate layer 44 and the second intermediate layer 48.

Here, by providing a slope to the refractive index n₁, the refractive index difference (nₚ−n₁) of the interface of the p-type layer 42 and the first intermediate layer 44 becomes lower than the refractive index difference (nᵢ−n₁) of the interface of the i-type layer 46 and the first intermediate layer 44 so that the light transmittance with respect to the light entering from the p-type layer 42 side can be further improved. On the other hand, when the light that has entered the i-type layer 46 is reflected by a location, such as between the n-type layer 50 and the rear electrode layer 34, and reaches the interface of the i-type layer 46 and the first intermediate layer 44, the reflectance to the i-type layer 46 can be increased due to the refractive index difference (nᵢ−n₁) of the interface of the i-type layer 46 and the first intermediate layer 44.

Furthermore, by providing a slope to the refractive index n₂ the refractive index difference (nₙ−n₂) of the interface of the n-type layer 50 and the second intermediate layer 48 becomes lower than the refractive index difference (nᵢ−n₂) of the interface of the i-type layer 46 and the second intermediate layer 48 and the light transmittance with respect to the light reflected, such as by the rear electrode layer 34, and entering from the n-type layer 50 side, can be improved. On the other hand, when the light that has once entered the i-type layer 46 reaches the interface of the i-type layer 46 and the second intermediate layer 48, the reflectance to the i-type layer 46 can be increased due to the refractive index difference (nᵢ−n₂) of the interface of the i-type layer 46 and the second intermediate layer 48.

In this manner, the light utilization efficiency at the i-type layer 46 of the μc-Si unit 204 constituting the bottom cell can be improved.

Here, the refractive index n₁ of the first intermediate layer 44 at the interface with the p-type layer 42 is preferably set higher than the refractive index n₂ of the second intermediate layer 48 at the interface with the n-type layer 50. Since a refractive index nₚ of the p-type layer 42 and the refractive index nₙ of the n-type layer 50 are comparable, the efficiency for guiding light to the i-type layer 46 can be increased more at the interface of the p-type layer 42 and the first intermediate layer 44 than at the interface of the n-type layer 50 and the second intermediate layer 48.

Furthermore, a film thickness d₁ of the first intermediate layer 44 is preferably less than or equal to a film thickness d₂ of the second intermediate layer 48. Thus, although the reflectance at the interface of the first intermediate layer 44 and the i-type layer 46 slightly decreases from the reflectance at the interface of the i-type layer 46 and the second intermediate layer 48, light absorption at the first intermediate layer 44, which is the light incident side from the transparent insulation substrate 30, is controlled so that the amount of light reaching the i-type layer 46 can be increased and the power generation efficiency of the overall photoelectric conversion device 200 can be increased. On the other hand, although the light absorption amount at the second intermediate layer 48 becomes higher than the light absorption amount at the first intermediate layer 44, the light reflected from the rear electrode layer 34 and entering the second intermediate layer 48 is less than the light entering the first intermediate layer 44 from the transparent insulation substrate 30 side so that by increasing the reflectance at the interface of the i-type layer 46 and the second intermediate layer 48 the light trapping effect at the i-type layer 46 increases and the power generation efficiency of the overall photoelectric conversion device 200 can be increased.

More specifically, the film thicknesses d₁ and d₂ of the first intermediate layer 44 and the second intermediate layer 48 are preferably from 30 nm to 100 nm. In particular, the film thickness d₁ of the first intermediate layer 44 is preferably in a range of 30 nm to 50 nm and the film thickness d₂ of the second intermediate layer 48 is preferably greater than or equal to the film thickness d₁ of the first intermediate layer 44 and in a range of 50 nm to 100 nm.

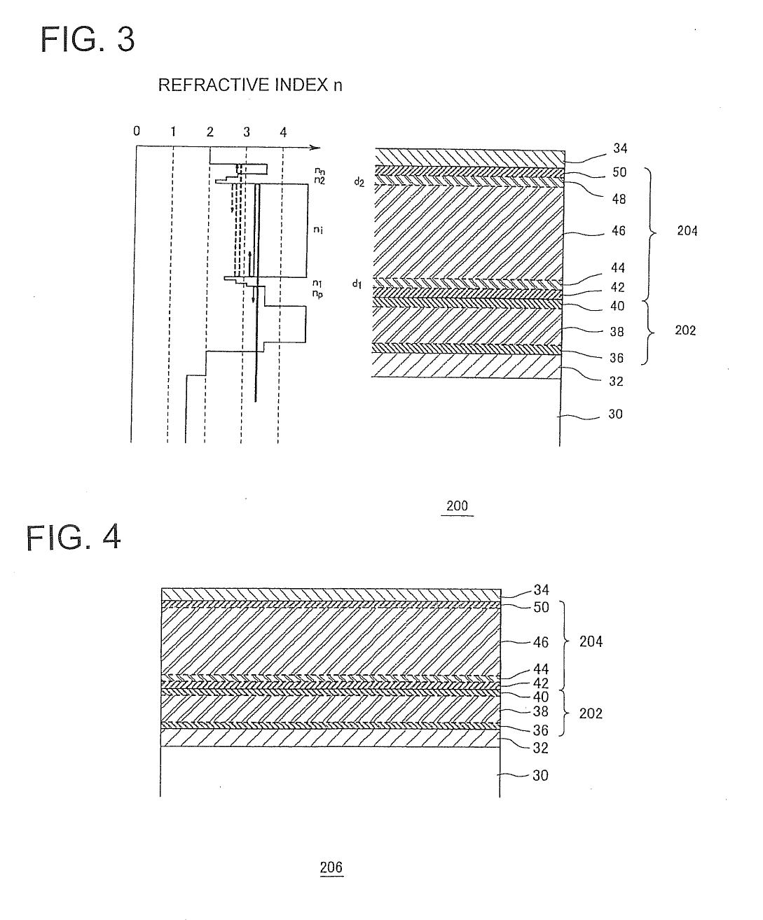

Furthermore, the refractive indices n₁ and n₂ of the first intermediate layer 44 and the second intermediate layer 48 are not limited to slope continuously in the film thickness direction and may be changed stepwise as shown in FIG. 3.

The refractive index of each layer can be determined by component analysis using energy-dispersive X-ray spectroscopy (EDX) on the cross section of the photoelectric conversion device 200. In EDX-based component analysis, when the content of oxygen (O) of a target cross section region is higher than that of another cross section region, the target cross section region can be judged to have a lower refractive index than the other cross section region. For example, if a layer having an oxygen content higher than the i-type layer 46 is provided on both sides of the i-type layer 46 of the μc-Si unit 204, a structure can be judged to have the structure of the photoelectric conversion device 200 of the embodiment. Furthermore, the relationship of the refractive index of the first intermediate layer 44 and the second intermediate layer 48 and that of the p-type layer 42 and the n-type layer 50 can be judged.

Regarding the relationship of the refractive index of each layer, other embodiments and modification examples to be described hereinafter can be judged similarly.

Although a layer containing silicon oxide doped with an impurity was applied for the first intermediate layer 44 and the second intermediate layer 48, the embodiment is not intended to be limited to this. For example, the first intermediate layer 44 and the second intermediate layer 48 may use a transparent conductive oxide (TCO), such as zinc oxide (ZnO). In particular, the use of zinc oxide (ZnO) doped with magnesium (Mg) is preferable. The transparent conductive oxide (TCO) can be formed, for example, by sputtering or CVD.

### Second Embodiment

As shown in FIG. 4, a photoelectric conversion device 206 of the second embodiment has a structure where only the first intermediate layer 44 of the photoelectric conversion device 200 of the first embodiment is provided and the second intermediate layer 48 is not.

In this case, the action of the first intermediate layer 44 is similar to the photoelectric conversion device 200 of the first embodiment. On the other hand, since the second intermediate layer 48 is not provided, light penetrating the interface of the p-type layer 42 and the first intermediate layer 44 and entering the i-type layer 46 is reflected at the interface of the n-type layer 50 and the rear electrode layer 34 and returned to the i-type layer 46. When the reflected light reaches the interface of the i-type layer 46 and the first intermediate layer 44, the light is reflected again due to the mutual refractive index difference and returned to the i-type layer 46. In this manner, the light trapping effect at the i-type layer 46 of the μc-Si unit 204 constituting the bottom cell is obtained due to the first intermediate layer 44 and the rear electrode layer 34.

It should be noted the structure may be provided with only the second intermediate layer 48 and without the first intermediate layer 44. In this case, the action of the second intermediate layer 48 is similar to the photoelectric conversion device 200 of the first embodiment. Since the first intermediate layer 44 is not provided, the light trapping effect with respect to the i-type layer 46 decreases while the reflective effect due to the second intermediate layer 48 is obtained.

### Third Embodiment

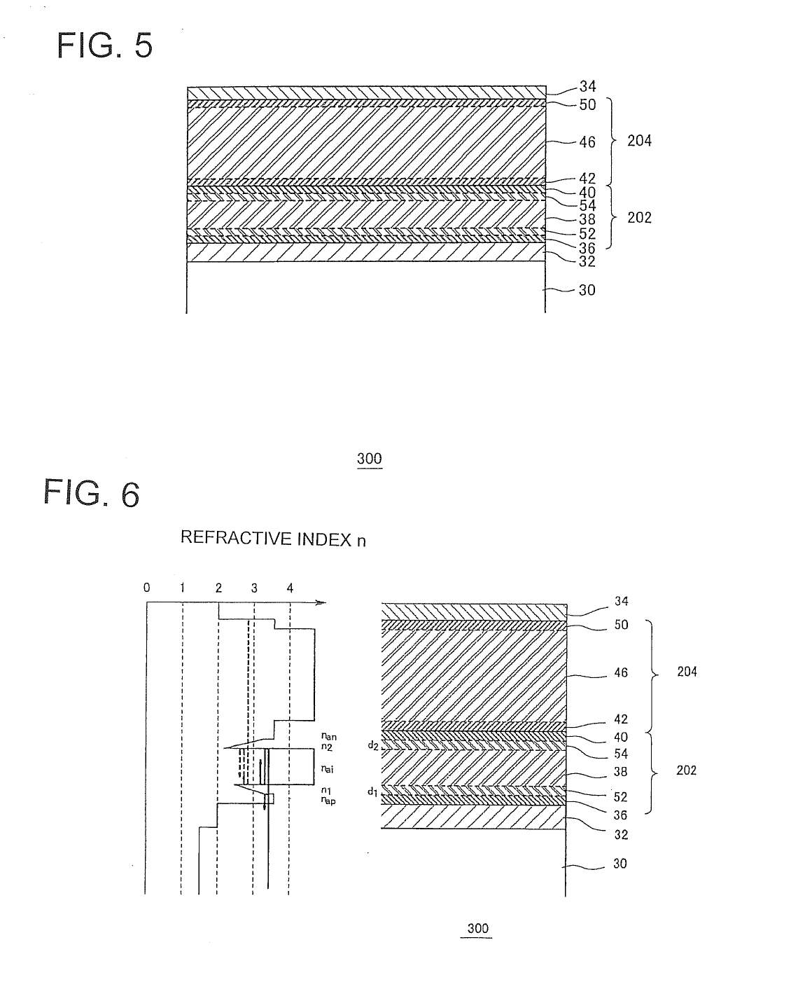

FIG. 5 is a cross sectional view showing the structure of a photoelectric conversion device 300 of the third embodiment. The photoelectric conversion device 300 of the embodiment provides a first intermediate layer 52 and a second intermediate layer 54 in the a-Si unit 202 instead of the first intermediate layer 44 and the second intermediate layer 48 provided in the μc-Si unit 204 as in the photoelectric conversion device 200 of the first embodiment. Since the film formation method for each layer is similar to that for the first embodiment, their description will be omitted.

FIG. 6 shows the refractive index of each layer of the photoelectric conversion device 300 of the embodiment. As shown in FIG. 6, the refractive index n₁ of the first intermediate layer 52 and the refractive index n₂ of the second intermediate layer 54 are set lower than a refractive index nₐᵢ of the i-type layer 38 of the a-Si unit 202 for which light is to be trapped. Furthermore, the refractive index n₁ of the first intermediate layer 52 is set less than or equal to a refractive index nₐₚ of the abutting p-type layer 36. Furthermore, the refractive index n₂ of the second intermediate layer 54 is set less than or equal to a refractive index nₐₙ of the abutting n-type layer 40.

Moreover, in the embodiment, the refractive index of the first intermediate layer 52 is changed in the film thickness direction. As shown in FIG. 6, the first intermediate layer 52 is formed so that the refractive index n₁ gradually increases from the i-type layer 38 side toward the p-type layer 36 side. Furthermore, the second intermediate layer 54 is formed so that the refractive index n₂ thereof changes along the film thickness direction. The second intermediate layer 54, as shown in FIG. 6, is formed so that the refractive index n₂ gradually increases from the i-type layer 38 side toward the n-type layer 40 side.

The refractive index n₁ of the first intermediate layer 52 is preferably set so as to be approximately equal to the refractive index nₐₚ of the p-type layer 36 at the interface with the p-type layer 36. More specifically, since the refractive index nₐₚ of the p-type layer 36 is approximately 3.6, the refractive index n₁ of the first intermediate layer 52 at the interface with the p-type layer 36 is preferably set to approximately 3.6. Furthermore, the refractive index n₁ of the first intermediate layer 52 is preferably set as low as possible to an extent where the film property does not deteriorate at the interface with the i-type layer 38. More specifically, the refractive index n₁ of the first intermediate layer 52 at the interface with the i-type layer 38 is preferably set to approximately 2.1.

The refractive index n₂ of the second intermediate layer 54 is preferably set so as to be approximately equal to the refractive index nₐₙ of the n-type layer 40 at the interface with the n-type layer 40. More specifically, since the refractive index nₐₙ of the n-type layer 40 is approximately 3.6, the refractive index n₂ of the second intermediate layer 54 at the interface with the n-type layer 40 is preferably set to approximately 3.6. Furthermore, the refractive index n₂ of the second intermediate layer 54 is preferably set as low as possible to an extent where the film property does not deteriorate at the interface with the i-type layer 38. More specifically, the refractive index n₂ of the second intermediate layer 54 at the interface with the i-type layer 38 is preferably set to approximately 2.1.

Operations of the first intermediate layer 52 and the second intermediate layer 54 will be described hereinafter. As shown by the arrow (solid line) in FIG. 6, the light penetrating the interface of the p-type layer 36 and the first intermediate layer 52 and entering the i-type layer 38 is reflected due the mutual refractive index difference at the interface of the i-type layer 38 and the second intermediate layer 54 and returned to the i-type layer 38. Furthermore, when the light reflected at the interface of the i-type layer 38 and the second intermediate layer 54 reaches the interface of the i-type layer 38 and the first intermediate layer 52, the light is again reflected due to the mutual refractive index difference and returned to the i-type layer 38. In this manner, the light trapping effect at the i-type layer 38 of the a-Si unit 202 constituting the top cell is obtained due to the first intermediate layer 52 and the second intermediate layer 54.

Furthermore, as shown by the arrow (broken line) in FIG. 6, part of the light penetrates the interface of the i-type layer 38 and the second intermediate layer 54. However, the light passes the n-type layer 40, the p-type layer 42, the i-type layer 46, and the n-type layer 50, reaches the n-type layer 50 and the rear electrode layer 34, is reflected due to the refractive index difference of the n-type layer 50 and the rear electrode layer 34, and is again returned to the i-type layer 38. Then, as described above, the light reflected by the rear electrode layer 34 is also trapped at the i-type layer 38 due to the first intermediate layer 52 and the second intermediate layer 54.

Here, by providing a slope to the refractive index n₁, the refractive index difference (nₐₚ−n₁) of the interface of the p-type layer 36 and the first intermediate layer 52 becomes lower than the refractive index difference (nₐᵢ−n₁) of the interface of the i-type layer 38 and the first intermediate layer 52 so that the light transmittance with respect to the light entering from the p-type layer 36 side can be further improved. On the other hand, when the light that has once entered the i-type layer 38 is reflected by, for example, the interface of the second intermediate layer 54 and the n-type layer 40, and reaches the interface of the i-type layer 38 and the first intermediate layer 52, the reflectance to the i-type layer 38 can be increased due to the refractive index difference (nₐᵢ−n₁) of the interface of the i-type layer 38 and the first intermediate layer 52.

Furthermore, by providing a slope to the refractive index n₂ the refractive index difference (nₐₙ−n₂) of the interface of the n-type layer 40 and the second intermediate layer 54 becomes lower than the refractive index difference (nₐᵢ−n₂) of the interface of the i-type layer 38 and the second intermediate layer 54, and the light transmittance with respect to the light reflected, such as by the rear electrode layer 34, and entering from the n-type layer 40 side, can be improved. On the other hand, when the light that has once entered the i-type layer 38 reaches the interface of the i-type layer 38 and the second intermediate layer 54, the reflectance to the i-type layer 46 can be increased due to the refractive index difference (nₐᵢ−n₂) of the i-type layer 38 and the second intermediate layer 54.

In this manner, the light utilization efficiency at the i-type layer 38 of the a-Si unit 202 constituting the top cell can be improved.

Here, the refractive index n₁ of the first intermediate layer 52 at the interface with the p-type layer 36 is preferably set higher than the refractive index n₂ of the second intermediate layer 54 at the interface with the n-type layer 40. Since the refractive index nₐₚ of the p-type layer 36 and the refractive index nₐₙ of the n-type layer 40 are comparable, the efficiency for guiding light to the i-type layer 38 can be increased more at the interface of the p-type layer 36 and the first intermediate layer 52 than at the interface of the n-type layer 40 and the second intermediate layer 54.

Furthermore, the film thickness d₁ of the first intermediate layer 52 is preferably less than or equal to the film thickness d₂ of the second intermediate layer 54. Thus, although the reflectance at the interface of the first intermediate layer 52 and the i-type layer 38 slightly decreases from the reflectance at the interface of the i-type layer 38 and the second intermediate layer 54, light absorption at the first intermediate layer 52, which is the light incident side from the transparent insulation substrate 30, is controlled so that the amount of light reaching the i-type layer 38 can be increased and the power generation efficiency of the overall photoelectric conversion device 300 can be increased. On the other hand, although the light absorption amount at the second intermediate layer 54 becomes higher than the light absorption amount at the first intermediate layer 52, the light reflected and entering the second intermediate layer 54 is less than the light entering the first intermediate layer 52 from the transparent insulation substrate 30 side so that by increasing the reflectance at the interface of the i-type layer 38 and the second intermediate layer 54 the light trapping effect at the i-type layer 38 increases and the power generation efficiency of the overall photoelectric conversion device 300 can be increased.

More specifically, the film thicknesses d₁ and d₂ of the first intermediate layer 52 and the second intermediate layer 54 are preferably from 30 nm to 100 nm. In particular, the film thickness d₁ of the first intermediate layer 52 is preferably in a range of 30 nm to 50 nm and the film thickness d₂ of the second intermediate layer 54 is preferably greater than or equal to the film thickness d₁ of the first intermediate layer 52 and in a range of 50 nm to 100 nm.

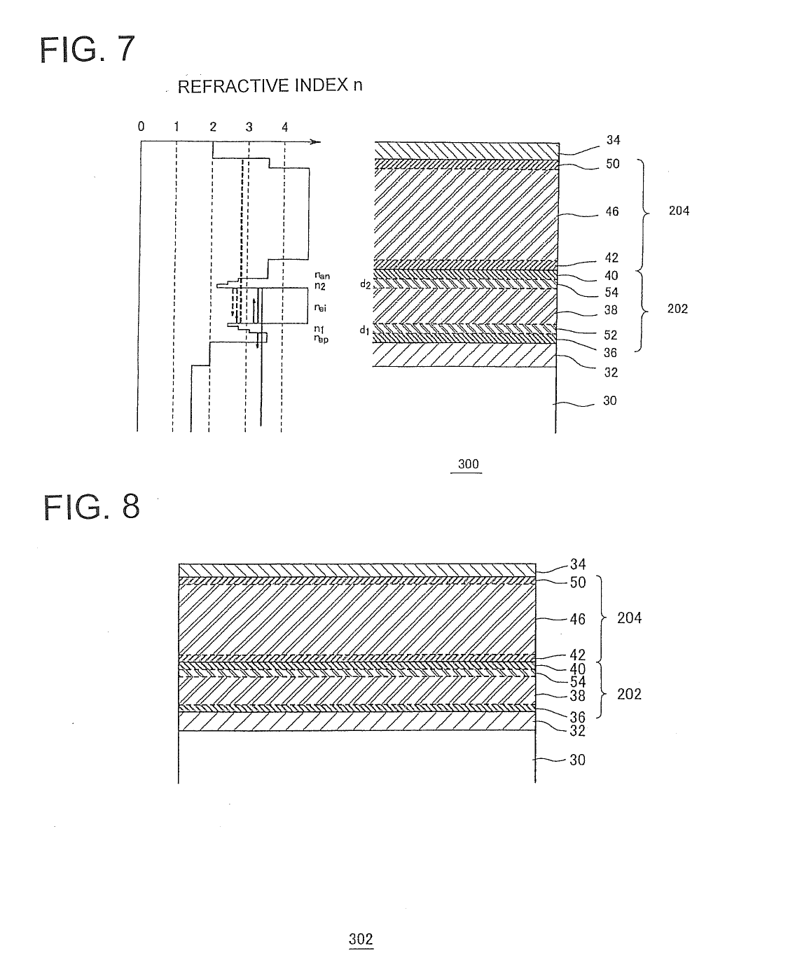

Furthermore, the refractive indices n₁ and n₂ of the first intermediate layer 52 and the second intermediate layer 54 are not limited to slope continuously in the film thickness direction and may be changed stepwise as shown in FIG. 7.

Although a layer containing silicon oxide doped with an impurity was applied for the first intermediate layer 52 and the second intermediate layer 54, the embodiment is not intended to be limited to this. For example, the first intermediate layer 52 and the second intermediate layer 54 may use a transparent conductive oxide (TCO), such as zinc oxide (ZnO). In particular, the use of zinc oxide (ZnO) doped with magnesium (Mg) is preferable. The transparent conductive oxide (TCO) can be formed, for example, by sputtering or CVD.

### Fourth Embodiment

As shown in FIG. 8, a photoelectric conversion device 302 of the fourth embodiment has a structure where only the second intermediate layer 54 of the photoelectric conversion device 300 of the third embodiment is provided and the first intermediate layer 52 is not.

In this case, the action of the second intermediate layer 54 is similar to the photoelectric conversion device 300 of the third embodiment. Providing the second intermediate layer 54 can increase the reflection of light to the i-type layer 38 and can improve the power generation efficiency at the a-Si unit 202 constituting the top cell.

It should be noted the structure may be provided with only the first intermediate layer 52 and without the second intermediate layer 54. In this case, the action of the first intermediate layer 52 is similar to the photoelectric conversion device 300 of the third embodiment. On the other hand, since the second intermediate layer 54 is not provided, the light not absorbed by the i-type layer 38 passes the n-type layer 40 and the μc-Si unit 204 constituting the bottom cell, reaches the rear electrode layer 34 and is reflected, and is further returned to the i-type layer 38 when not absorbed by the μc-Si unit 204 constituting the bottom cell. When the reflected light reaches the interface of the i-type layer 38 and the first intermediate layer 52, the light is again reflected due to the mutual refractive index difference and returned to the i-type layer 38. In this manner, the light trapping effect is obtained at the a-Si unit 202 constituting the top cell and the μc-Si unit 204 constituting the bottom cell due to the first intermediate layer 52 and the rear electrode layer 34.

Furthermore, the structures in the first to fourth embodiments may be appropriately combined into a structure. As a result, the respective light trapping effects can be synergistically obtained and the power generation efficiency of the photoelectric conversion device can be increased.

### Fifth Embodiment

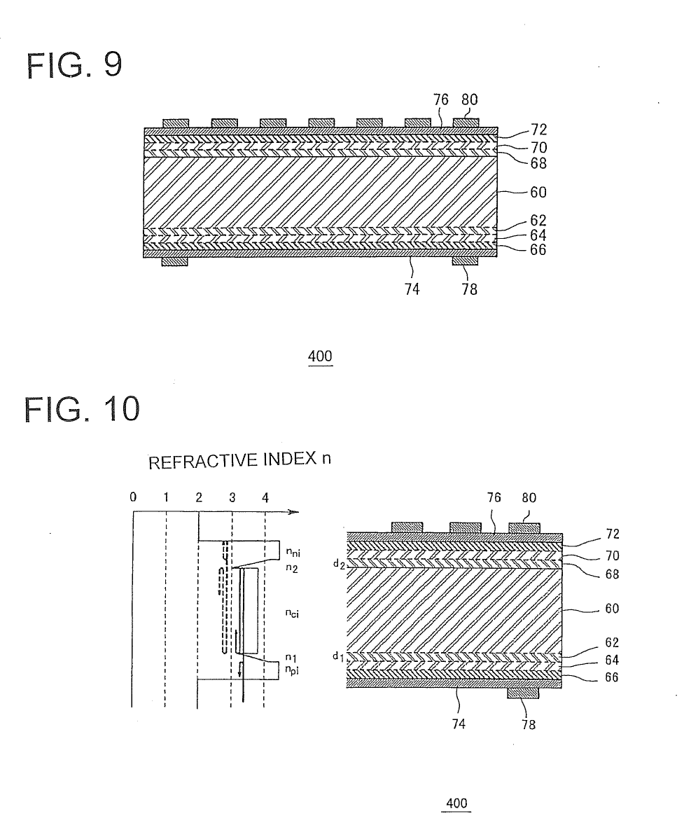

The present invention can be applied to a crystal-based photoelectric conversion device. FIG. 9 is a schematic cross sectional view showing the structure of a photoelectric conversion device 400 comprising a monocrystalline silicon layer 60.

The photoelectric conversion device 400 has a structure wherein a first intermediate layer 62, an intrinsic semiconductor layer 64, and a conductivity-type semiconductor layer 66 are sequentially formed on a front surface (first surface) of the monocrystalline silicon layer 60, and a second intermediate layer 68, an intrinsic semiconductor layer 70, and a conductivity type semiconductor layer 72 are formed on a rear surface (second surface) of the monocrystalline silicon layer 60.

The monocrystalline silicon layer 60 preferably uses n-type monocrystalline silicon (resistivity=approximately 0.5 to 4 Ωcm). For example, the monocrystalline silicon layer 60 is preferably a 100 mm square with a thickness of approximately 100 to 500 μm.

The first intermediate layer 62 is formed on the front surface (first surface) of the monocrystalline silicon layer 60. The first intermediate layer 62 can be formed in the same manner as the first intermediate layer 44 of the first embodiment. On the first intermediate layer 62 are formed by plasma CVD the intrinsic semiconductor layer 64 (film thickness: approximately 50 to 200 Å), which is a non-doped amorphous silicon layer, and the conductivity-type semiconductor layer 66 (film thickness: approximately 50 to 150 Å), which is a p-type amorphous silicon layer doped with a p-type dopant. Although the intrinsic semiconductor layer 64 and the conductivity-type semiconductor layer 66 used amorphous silicon, microcrystalline silicon may be used.

The second intermediate layer 68 is formed on the rear surface (second surface) of the monocrystalline silicon layer 60. The second intermediate layer 68 can be formed in the same manner as the second intermediate layer 48 of the first embodiment. On the second intermediate layer 68 are formed using plasma CVD the intrinsic semiconductor layer 70 (film thickness: approximately 5 to 200 Å), which is a non-doped amorphous silicon layer, and the conductivity-type semiconductor layer 72 (film thickness: approximately 100 to 500 Å), which is an n-type amorphous silicon layer. Although the intrinsic semiconductor layer 70 and the conductivity-type semiconductor layer 72 used amorphous silicon, microcrystalline silicon may be used.

Transparent conductive layers 74 and 76 are formed on and have approximately equal areas to the conductivity-type semiconductor layers 66 and 72. Furthermore, on the transparent conductive layers 74 and 76 are formed collector electrodes 78 and 80, such as from silver paste. The photoelectric conversion device 400 employs the transparent conductive layer 76 also on the rear surface (second surface) side so that light entering the rear surface side also contributes to power generation.

FIG. 10 shows the refractive index of each layer of the photoelectric conversion device 400. As shown in FIG. 10, the refractive index n₁ of the first intermediate layer 62 and the refractive index n₂ of the second intermediate layer 68 are set lower than a refractive index n_{ci} of the monocrystalline silicon layer 60 for which light is to be trapped. Furthermore, the refractive index n₁ of the first intermediate layer 62 is set less than or equal to a refractive index nₚᵢ of the abutting intrinsic semiconductor layer 64 and the conductivity-type semiconductor layer 66. Moreover, in the embodiment, the refractive index n₁ of the first intermediate layer 62 is changed in the film thickness direction. The first intermediate layer 62, as shown in FIG. 10, is formed so that the refractive index n₁ gradually increases from the monocrystalline silicon layer 60 side toward the intrinsic semiconductor layer 64 side.

Furthermore, the refractive index n₂ of the second intermediate layer 68 is set to less than or equal to a refractive index nₙᵢ of the abutting intrinsic semiconductor layer 70 and the conductivity-type semiconductor layer 72. Moreover, in the embodiment, the refractive index n₂ of the second intermediate layer 68 is changed in the film thickness direction. The second intermediate layer 68 is formed so that the refractive index n₂ gradually increases from the monocrystalline silicon layer 60 side toward the intrinsic semiconductor layer 70 side.

As a result, as shown by the arrow (solid line) in FIG. 10, the light penetrating the interface of the intrinsic semiconductor layer 64 and the first intermediate layer 62 and entering the monocrystalline silicon layer 60 is reflected due to the mutual refractive index difference at the interface of the monocrystalline silicon layer 60 and the second intermediate layer 68 and returned to the monocrystalline silicon layer 60. Moreover, when the light reflected at the interface of the monocrystalline silicon layer 60 and the second intermediate layer 68 reaches the interface of the monocrystalline silicon layer 60 and the first intermediate layer 62, the light is again reflected due to the mutual refractive index difference and returned to the monocrystalline silicon layer 60. Furthermore, as shown by the arrow (broken line) in FIG. 10, the light penetrating the interface of the intrinsic semiconductor layer 70 and the second intermediate layer 68 and entering the monocrystalline silicon layer 60 is reflected due to the mutual refractive index difference at the interface of the monocrystalline silicon layer 60 and the first intermediate layer 62 and returned to the monocrystalline silicon layer 60. Moreover, when the light reaches the interface of the monocrystalline silicon layer 60 and the second intermediate layer 68, the light is again reflected due to the mutual refractive index difference and returned to the monocrystalline silicon layer 60. In this manner, the light trapping effect at the monocrystalline silicon layer 60 is obtained due to the first intermediate layer 62 and the second intermediate layer 68.

Here, by providing a slope to the refractive index the refractive index difference (nₚᵢ−n₁) of the interface of the intrinsic semiconductor layer 64 and the first intermediate layer 62 becomes lower than the refractive index difference (n_{ci}−n₁) of the interface of the monocrystalline silicon layer 60 and the first intermediate layer 62 so that the light transmittance with respect to the light entering from the intrinsic semiconductor layer 64 side can be further improved. On the other hand, when the light that has entered the monocrystalline silicon layer 60 is reflected by a location, such as between the intrinsic semiconductor layer 70 and the rear electrode layer 76, and reaches the interface of the monocrystalline silicon layer 60 and the first intermediate layer 62, the reflectance to the monocrystalline silicon layer 60 can be increased due to the refractive index difference (n_{ci}−n₁) of the interface of the monocrystalline silicon layer 60 and the first intermediate layer 62.

Furthermore, by providing a slope to the refractive index n₂, the refractive index difference (nₙᵢ−n₂) of the interface of the intrinsic semiconductor layer 70 and the second intermediate layer 68 becomes lower than the refractive index difference (n_{ci}−n₂) of the interface of the monocrystalline silicon layer 60 and the second intermediate layer 68 and the light transmittance with respect to the light entering the intrinsic semiconductor layer 70 side can be improved. On the other hand, when the light that has entered the monocrystalline silicon layer 60 reaches the interface of the monocrystalline silicon layer 60 and the second intermediate layer 68, the reflectance to the monocrystalline silicon layer 60 can be increased due to the refractive index difference (n_{ci}−n₂) of the interface of the monocrystalline silicon layer 60 and the second intermediate layer 68.

As described hereinabove, by providing the first intermediate layer 62 and the second intermediate layer 68, the light trapping effect at the monocrystalline silicon layer 60 can be obtained and the light utilization efficiency can be increased.

The refractive index n₁ of the first intermediate layer 62 is preferably set so as to be approximately equal to the refractive index nₚᵢ of the intrinsic semiconductor layer 64 at the interface with the intrinsic semiconductor layer 64. The refractive index n₂ of the second intermediate layer 68 is preferably set so as to be approximately equal to the refractive index nₙᵢ of the intrinsic semiconductor layer 70 at the interface with the intrinsic semiconductor layer 70. Furthermore, the refractive index n₁ of the first intermediate layer 62 and the refractive index n₂ of the second intermediate layer 68 are preferably set as low as possible to an extent where the film property does not deteriorate at the interface with the monocrystalline silicon layer 60.

Furthermore, the film thickness d₁ of the first intermediate layer 62 is preferably set less than or equal to the film thickness d₂ of the second intermediate layer 68. Thus, although the reflectance at the interface of the first intermediate layer 62 and the monocrystalline silicon layer 60 slightly decreases from the reflectance at the interface of the monocrystalline silicon layer 60 and the second intermediate layer 68, light absorption at the first intermediate layer 62, which is arranged on the main light incident side, is controlled so that the amount of light reaching the monocrystalline silicon layer 60 can be increased and the power generation efficiency of the overall photoelectric conversion device 400 can be increased. On the other hand, although the light absorption amount at the second intermediate layer 68 becomes higher than the light absorption amount at the first intermediate layer 62, the light penetrating the second intermediate layer 68 and reaching the monocrystalline silicon layer 60 is less than the light penetrating the first intermediate layer 62 and reaching the monocrystalline silicon layer 60 so that by further increasing the reflectance at the interface of the monocrystalline silicon layer 60 and the second intermediate layer 68 the light trapping effect at the monocrystalline silicon layer 60 increases and the power generation efficiency of the overall photoelectric conversion device 400 can be increased.

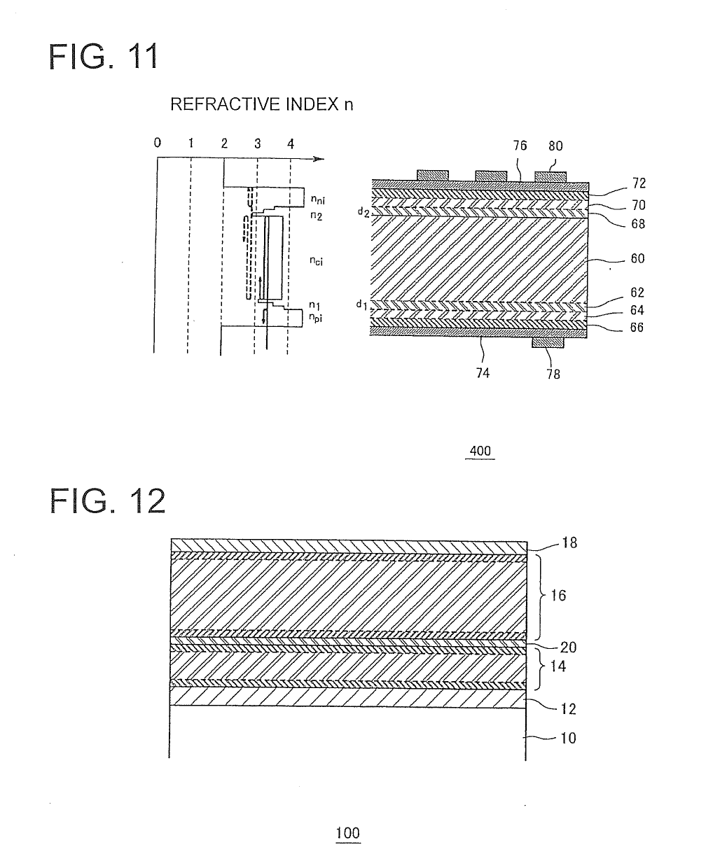

Furthermore, the refractive indices n₁ and n₂ of the first intermediate layer 62 and the second intermediate layer 68 are not limited to slope continuously in the film thickness direction and may be changed stepwise as shown in FIG. 11.

Providing at least one of either the first intermediate layer 62 or the second intermediate layer 68 is effective in improving the power generation efficiency of the photoelectric conversion device. Furthermore, in a photoelectric conversion device having two or more laminated layers of the monocrystalline silicon layer 60, which is the power generation layer, the light trapping effect can be obtained by providing the first intermediate layer 62 and the second intermediate layer 68 for every monocrystalline silicon layer 60.

### REFERENCE NUMERALS

10 substrate, 12 transparent electrode layer, 14 amorphous silicon photoelectric conversion unit (a-Si unit), 16 microcrystalline silicon photoelectric conversion unit (μc-Si unit), 20 intermediate layer, 30 transparent insulation substrate, 32 transparent conductive layer, 34 rear electrode layer, 36 p-type layer (a-Si), 38 i-type layer (a-Si), 40 n-type layer (a-Si), 42 p-type layer (μc-Si), 44, 56, 62 first intermediate layer, 46 i-type layer (μc-Si), 48, 58, 68 second intermediate layer, 50 n-type layer (μc-Si), 60 monocrystalline silicon layer, 64 intrinsic semiconductor layer, 66 conductivity-type semiconductor layer, 70 intrinsic semiconductor layer, 72 conductivity-type semiconductor layer, 74, 76 transparent conductive layer, 78, 80 collector electrode, 100, 200, 206, 300, 302, 400 photoelectric conversion device, 202 amorphous silicon photoelectric conversion unit (a-Si unit), 204 microcrystalline silicon photoelectric conversion unit (μc-Si unit).

What is claimed is:

1. A photoelectric conversion device, in which are laminated semiconductor films of a p-type layer, an i-type layer, and an n-type layer of, comprising:
an intermediate layer abutting said i-type layer and having a refractive index increasing from a side that abuts said i-type layer toward a side that does not abut said i-type layer within a range of refractive indices smaller than that of said i-type layer;
said intermediate layer comprising a first intermediate layer and a second intermediate layer disposed so as to sandwich said i-type layer.

2. A photoelectric conversion device according to claim 1, wherein:
said first intermediate layer is disposed near a light incident surface from said second intermediate layer; and
the refractive index of said first intermediate layer on the side abutting said i-type layer is higher than the refractive index of said second intermediate layer on the side abutting said i-type layer.

3. A photoelectric conversion device according to claims 1, wherein:
said first intermediate layer is disposed near a light incident surface from said second intermediate layer and has a film thickness less than or equal to said second intermediate layer.

4. A photoelectric conversion device according to claims 2, wherein:
said first intermediate layer is disposed near a light incident surface from said second intermediate layer and has a film thickness less than or equal to said second intermediate layer.
